(19) United States
(12) Patent Application Publication
(10) Pub. No.: US 2014/0353026 A1
(43) Pub. Date: Dec. 4, 2014

(54) WIRING BOARD

(71) Applicant: KYOCERA SLC Technologies Corporation, Yasu-shi (JP)

(72) Inventor: Seiji HATTORI, Otsu-shi (JP)

(73) Assignee: KYOCERA SLC TECHNOLOGIES CORPORATION, Yasu-shi (JP)

(21) Appl. No.: 14/291,462

(22) Filed: May 30, 2014

(30) Foreign Application Priority Data
May 30, 2013 (JP) 2013-113543
May 30, 2013 (JP) 2013-113544
May 30, 2013 (JP) 2013-113545
Sep. 30, 2013 (JP) 2013-203234
Sep. 30, 2013 (JP) 2013-203235
Sep. 30, 2013 (JP) 2013-203236
Feb. 26, 2014 (JP) 2014-035434
Feb. 26, 2014 (JP) 2014-035435
Feb. 26, 2014 (JP) 2014-035436
Feb. 26, 2014 (JP) 2014-035437

(51) Int. Cl. H05K 1/02; H05K 1/11; H05K 1/03

(52) U.S. Cl. CPC H05K 1/0271; H05K 1/0298; H05K 1/0306; H05K 1/112
USPC 174/262

(57) ABSTRACT

A wiring board according to the present invention includes an insulating layer 3, a semiconductor element mounting portion 1a, semiconductor element connection pads 11, via holes 8, and via conductors 10. The semiconductor element connection pads 11 aligned on the semiconductor element mounting portion 1a include first semiconductor element connection pads 11a and other second semiconductor element connection pads 11b, and the diameters of the via conductors 10 connected to the first semiconductor element connection pads 11a are larger than the diameters of the via conductors 10 connected to the second semiconductor element connection pads 11b.

### BACKGROUND OF THE INVENTION

1. Field of the Invention

The present invention relates to a wiring board for mounting a semiconductor element or the like thereon.

2. Description of Related Art

In recent years, advanced electronic appliances typified by a cellular phone or a music player have been developed. On a wiring board used in such an electronic appliance, an advanced large-size semiconductor element used for computation or the like may be mounted.

FIG. 15 shows a conventional wiring board E on which a large-size semiconductor element is mounted. FIG. 15A is an upper view of a wiring board E, and FIG. 15B is a sectional view along a line Y-Y in FIG. 15A. The wiring board E, as shown in FIG. 15B, includes an insulating board 21 in which a plurality of through holes 25 are formed, wiring conductors 22, an insulating layer 23 laminated on the upper surface of the insulating board 21, and a solder resist layer 24. On a central portion on the upper surface of the wiring board E, a semiconductor element mounting portion 21a for mounting a large size semiconductor element S thereon is formed.

Some of the wiring conductors 22 are adhered to the upper and lower surfaces of the insulating board 21 and the insides of the through holes 25. The wiring conductors 22 on the upper surface side of the insulating board 21 form lower-layer conductors 26 on the upper surface side of the wiring board E. The wiring conductors 22 on the lower surface of the insulating board 21 form external connection pads 27 connected to an external electric circuit board.

A plurality of via holes 28 are formed in the insulating layer 23. Some of the wiring conductors 22 are adhered to the upper surface of the insulating layer 23 and the insides of the via holes 28. The wiring conductors 22 adhering to the upper surface of the insulating layer 23 form upper-layer conductors 29 on the upper surface side of the wiring board E. The wiring conductors 22 adhering to the insides of the via holes 28 form via conductors 30 connecting the upper-layer conductors 29 and the lower-layer conductors 26 to each other.

On the semiconductor element mounting portion 21a, semiconductor element connection pads 31 connected to electrodes T of the semiconductor element S are formed into a lattice pattern. The semiconductor element connection pads 31 are connected to the lower-layer conductors 26 with the via conductors 30 formed immediately under the semiconductor element connection pads 31. All the via conductors 30 have equal diameters on the semiconductor element mounting portion 21a.

The solder resist layer 24 adhered to the upper surface of the insulating layer 23 and the lower surface of the insulating board 21. The solder resist layer 24 on the upper surface side has first openings 24a for exposing the semiconductor element connection pads 31. The solder resist layer 24 on the lower surface side has second openings 24b for exposing the external connection pads 27. The electrodes T of the semiconductor element S are connected to the corresponding semiconductor element connection pads 31 through solder, respectively, and the external connection pads 27 are connected to wiring conductors of an external electric circuit board through solder, so that the semiconductor element S operate by being electrically connected to the external electric circuit board.

When the semiconductor element S increases in size with development of an advanced electric appliance, a heat history applied when the semiconductor element S is connected to the wiring board E with solder or when the semiconductor element S operates causes a large difference between the thermal expansion and contraction of the semiconductor element S and the thermal expansion and contraction of the wiring board E. As a result, large thermal stress is generated between the electrodes T of the semiconductor element S and the semiconductor element connection pads 31 connected thereto, and the thermal stress is intensively loaded to the connection portions between the via conductors 30 and the lower-layer conductors 26. In particular, at an outer peripheral corner portion of the semiconductor element mounting portion 21a located at a position distant from the central portion of the semiconductor element mounting portion 21a, the largest difference in thermal expansion and contraction occurs between the semiconductor element S and the wiring board E. For this reason, cracks are easily formed in a bonding surface between the via conductors 30 and the lower-layer conductors 26 at the outer peripheral corner portion of the semiconductor element mounting portion 21a, and the semiconductor element S may be unable to be stably operated.

Furthermore, on the wiring board, a plurality of semiconductor elements having various functions may be mounted. Examples of such a wiring board include a wiring board in which a large-size semiconductor element for computation and a small-size semiconductor element for memory are mounted on the same plane, a wiring board in which a small-size semiconductor element for memory and a large-size semiconductor element for computation are formed on an upper surface and a lower surface, respectively, and the like.

FIG. 16 shows a conventional wiring board F in which a plurality of semiconductor elements are mounted on the same plane. The wiring board F is basically similar to the wiring board E shown in FIG. 15 except that second mounting portions 21b for mounting small-size second semiconductor elements S2 thereon are formed on an upper outer peripheral portion.

On the first mounting portion 21a, first semiconductor element connection pads 31a connected to electrodes T1 of a first semiconductor element S1 are formed with an arrangement corresponding to the arrangement of the electrodes T1. The first semiconductor element connection pads 31a are connected to the lower-layer conductors 26 with the first via conductors 30a formed immediately under the semiconductor element connection pads 31a. On the second mounting portions 21b, second semiconductor element connection pads 31b connected to electrodes T2 of the second semiconductor elements S2 are formed with an arrangement corresponding to the arrangement of the electrodes T2. The second semiconductor element connection pads 31b are connected to the lower-layer conductors 26 with second via conductors 30b formed immediately under the second semiconductor element connection pads 31b. The electrodes T1 of the first semiconductor element S1 are arranged with a first electrode pitch P1 that is relatively large, and the second semiconductor elements S2 are arranged at a second electrode pitch P2 smaller than the first electrode pitch P1. The first via conductor 30a and the second via conductor 30b have the equal diameters.

The solder resist layer 24 is adhered to the upper surface of the insulating layer 23 and the lower surface of the insulating board 21. The solder resist layer 24 has first openings 24a and third openings 24c for exposing the first and second semiconductor element connection pads 31a and 31b. The solder resist layer 24 on the lower surface side has second openings 24b for exposing the external connection pads 27. The electrodes T1 and T2 of the first and second semiconductor elements S1 and S2 are connected to the corresponding first and second semiconductor element connection pads 31a and 31b through solder, respectively, and the external connection pads 27 are connected to wiring conductors of an external electric circuit board through solder, so that the first and second semiconductor elements S1 and S2 operate by being electrically connected to the external electric circuit board.

FIG. 17 shows a conventional wiring board G in which a plurality of semiconductor elements are mounted on upper and lower surfaces. The wiring board G is basically similar to the wiring board F shown in FIG. 16 except that the first mounting portion 21a and the second mounting portions 21b are not formed on the same plane as that of the wiring board but the first mounting portion 21a is formed on the lower surface of the wiring board and the second mounting portions 21b are formed on the upper surface. On the wiring board F in FIG. 16, since the first mounting portion 21a and the second mounting portions 21b are formed on the same plane of the wiring board, the insulating layer 23 is laminated on only the upper surface of the insulating board 21. On the other hand, on the wiring board G in FIG. 17, a first insulating layer 23a and a second insulating layer 23b are laminated on both surfaces of the insulating board 21.

The wiring conductors 22 on the lower surface of the insulating board 21 form first lower-layer conductors 26a on the lower surface side of the wiring board G. The wiring conductors 22 on the upper surface side of the insulating board 21 form second lower-layer conductors 26b on the upper surface side of the wiring board G. The wiring conductors 22 adhering to the lower surface of the first insulating layer 23a form first upper-layer conductors 29a on the lower surface side of the wiring board G. The wiring conductors 22 adhering to the upper surface of the second insulating layer 23b form second upper-layer conductors 29b on the upper surface side of the wiring board G. Furthermore, in the first semiconductor element S1, external connection electrodes T3 connected to an external electric circuit board are formed on a surface opposing a surface on which the electrodes T1 are formed.

The solder resist layer 24 is adhered to the lower surface of the first insulating layer 23a and the upper surface of the second insulating layer 23b. The solder resist layer 24 on the first insulating layer 23a side has first openings 24a for exposing the first semiconductor element connection pads 31a. The solder resist layer 24 on the second insulating layer 23b side has third openings 24c for exposing the second semiconductor element connection pads 31b. The electrodes T1 and T2 of the first and second semiconductor elements S1 and S2 are connected to the corresponding first and second semiconductor element connection pads 31a and 31b through solder, respectively, and the external connection electrodes T3 are connected to wiring conductors of an external electric circuit board through solder, so that the first and second semiconductor elements S1 and S2 operate by being electrically connected to the external electric circuit board.

When the semiconductor element S1 increases in size with development of an advanced electronic appliance, a heat history applied when the first semiconductor element S1 is connected to the wiring boards F and G with solder or when the semiconductor element S1 operates causes a large difference between the thermal expansion and contraction of the first semiconductor element S1 and the thermal expansion and contraction of the wiring boards F and G. As a result, large thermal stress is generated between the electrodes T1 of the semiconductor element S1 and the first semiconductor element connection pads 31a connected thereto, and the thermal stress is intensively loaded to the connection portions between the via conductors 30a and the lower-layer conductors 26 and 26a. Thus, cracks are easily formed in a bonding surface between the first via conductors 30a and the lower-layer conductors 26 and 26a, and the first semiconductor element S1 may be unable to be stably operated.

Such a conventional wiring board is described in, for example, Japanese Unexamined Patent Publication No. 2006-73593, Japanese Unexamined Patent Publication No. 2009-71299, Japanese Unexamined Patent Publication No. 2004-87837, Japanese Unexamined Patent Publication No. 2006-41242, and Japanese Unexamined Patent Publication No. 2003-324180.

### SUMMARY OF THE INVENTION

The present invention improves bonding strengths between via conductors and lower-layer conductors to suppress cracks from being formed between the via conductors and the lower-layer conductors due to stress generated by the thermal expansion and contraction of a semiconductor element and the thermal expansion and contraction of a wiring board. In this manner, it is an object to provide a wiring board that makes it possible to stably operate a semiconductor element.

In a first aspect of the present invention, there is provided a wiring board including an insulating layer having lower-layer conductors on a lower surface of the insulating layer, a semiconductor element mounting portion formed on the insulating layer, a plurality of semiconductor element connection pads arranged in a lattice pattern on the semiconductor element mounting portion, via holes formed in the insulating layer under the semiconductor element connection pads with the lower-layer conductors as bottom surfaces, and via conductors formed integrally with the semiconductor element connection pads and formed in the via holes to be electrically connected to the lower-layer conductor, wherein the semiconductor element connection pads include first semiconductor element connection pads formed at outer peripheral corner portions of the semiconductor element mounting portion and other second semiconductor element connection pads, and diameters of the via conductors connected to the first semiconductor element connection pads are larger than diameters of the via conductors connected to the second semiconductor element connection pads.

In a second aspect of the present invention, there is provided a wiring board including an insulating layer having lower-layer conductors on a lower surface of the insulating layer, a semiconductor element mounting portion formed on the insulating layer, a plurality of semiconductor element connection pads arranged in a lattice pattern on the semiconductor element mounting portion, via holes formed in the insulating layer under the semiconductor element connection pads with the lower-layer conductors as bottom surfaces, and via conductors formed integrally with the semiconductor element connection pads and formed in the via holes to be electrically connected to the lower-layer conductor, wherein the semiconductor element connection pads include first semiconductor element connection pads formed at outer peripheral corner portions of the semiconductor element mounting portion and other second semiconductor element connection pads, and with respect to at least the first semiconductor element connection pads, a plurality of via conductors are formed for each of the first semiconductor element connection pads.

In a third aspect of the present invention, there is provided a wiring board including an insulating layer having lower-layer conductors on a lower surface of the insulating layer, a first mounting portion formed on the insulating layer and on which a first semiconductor element having a first electrode pitch is mounted, a second mounting portion formed on the insulating layer and on which a second semiconductor element having a second electrode pitch smaller than the first electrode pitch and having diagonal lines shorter than diagonal lines of the first semiconductor element is mounted, first semiconductor element connection pads formed on the first mounting portion with the same pitch as the first electrode pitch, second semiconductor element connection pads formed on the second mounting portion with the same pitch as the second electrode pitch, first via holes formed in the insulating layer under the first semiconductor element connection pads, second via holes formed in the insulating layer under the second semiconductor element connection pads, first via conductors formed integrally with the first semiconductor element connection pads, and formed in the first via holes to be electrically connected to the lower-layer conductor, and second via conductors formed integrally with second semiconductor element connection pads, and formed in the second via holes to be electrically connected to the lower-layer conductor, wherein diameters of the first via conductors are larger than diameters of the second via conductors.

In a fourth aspect of the present invention, there is provided a wiring board including an insulating board having first lower-layer conductors on a lower surface of the insulating board and second lower-layer conductors on an upper surface of the insulating board, a first insulating layer laminated on the lower surface of the insulating board to cover the first lower-layer conductor, a second insulating layer laminated on the upper surface of the insulating board to cover the second lower-layer conductor, a first mounting portion formed on the first insulating layer and on which a first semiconductor element having a first electrode pitch is mounted, a second mounting portion formed on the second insulating layer and on which a second semiconductor element having a second electrode pitch smaller than the first electrode pitch and having diagonal lines shorter than diagonal lines of the first semiconductor element is mounted, first semiconductor element connection pads formed with the same pitch as the first electrode pitch on the first mounting portion, second semiconductor element connection pads formed with the same pitch as the second electrode pitch on the second mounting portion, first via holes formed in the first insulating layer under the first semiconductor element connection pads, second via holes formed in the second insulating layer under the second semiconductor element connection pads, first via conductors formed integrally with the first semiconductor element connection pads and formed in the first via holes to be electrically connected to the first lower-layer conductor, and second via conductors formed integrally with the second semiconductor element connection pads and formed in the second via holes to be electrically connected to the second lower-layer conductor, wherein diameters of the first via conductors are larger than diameters of the second via conductors.

In the first aspect of the present invention, diameters of the via conductors connected to the first semiconductor element connection pads formed at the outer peripheral corner portions of the semiconductor element mounting portion are larger than those of the via conductors connected to the other second semiconductor element connection pads. According to the second aspect of the present invention, with respect to at least the first semiconductor element connection pads, a plurality of via conductors are formed for each of the first semiconductor element connection pads. For this reason, a connection surface between each of the via conductors connected to the first semiconductor element connection pads and the lower-layer conductors increases. As a result, bonding strengths between the via conductors connected to the first semiconductor element connection pads and the lower-layer conductors can be improved. Thus, there can be provided a wiring board in which, at the outer peripheral corner portions of the semiconductor element mounting portion located at a position being distant from a central portion of the semiconductor element mounting portion, cracks can be suppressed from being formed in a bonding surface between the via conductors and the lower-layer conductors at each of the outer peripheral corner portions of the semiconductor element mounting portion by stress generated by a difference between the thermal expansion and contraction of the semiconductor element and the thermal expansion and contraction of the wiring board to make it possible to stably operate the semiconductor element.

According to the third aspect of the present invention, each of the first via conductors formed integrally with each of the first semiconductor element connection pads to which electrodes of the first semiconductor element are connected has a diameter larger than that of each of the second via conductors formed integrally with each of the second semiconductor element connection pads to which electrodes of the second semiconductor element are connected. For this reason, a connection surface between each of the first via conductors and the lower-layer conductors increases. As a result, bonding strengths between the first via conductors and the lower-layer conductors can be improved. Thus, there can be provided a wiring board in which cracks can be suppressed from being formed between the first via conductors and the lower-layer conductors by stress generated by a difference between the thermal expansion and contraction of the first semiconductor element having diagonal lines longer than the diagonal lines of the second semiconductor element and the thermal expansion and contraction of the wiring board to make it possible to stably operate the semiconductor elements. Since the electrode pitch of the first semiconductor element is larger than the electrode pitch of the second semiconductor element, even though the first via conductors have large diameters, a sufficient insulating space can be made between the first via conductors. Furthermore, since the second semiconductor element has short diagonal lines, large stress generated by a difference between the thermal expansion and contraction of the second semiconductor element and the thermal expansion and contraction of the wiring board does not occur. For this reason, even though the diameter of the second via conductors is still small, cracks are not formed between the second via conductors and the lower-layer conductor.

According to a fourth aspect of the present invention, each of the first via conductor formed integrally with each of the first semiconductor element connection pads to which electrodes of the first semiconductor element are connected has a diameter larger than that of each of the second via conductor formed integrally with each of the second semiconductor element connection pads to which the electrodes of the second semiconductor element are connected. For this reason, a connection surface between each of the first via conductors and the first lower-layer conductors increases. As a result, bonding strength between the first via conductors and the first lower-layer conductors can be improved. Thus, there can be provided a wiring board in which cracks can be suppressed from being formed between the first via conductors and the first lower-layer conductors by stress generated by a difference between the thermal expansion and contraction of the first semiconductor element having diagonal lines longer than the diagonal lines of the second semiconductor element and the thermal expansion and contraction of the wiring board to make it possible to stably operate the semiconductor elements. Since the electrode pitch of the first semiconductor element is larger than the electrode pitch of the second semiconductor element, even though the first via conductors have large diameters, a sufficient insulating space can be made between the first via conductors. Furthermore, since the second semiconductor element has short diagonal lines, large stress generated by a difference between the thermal expansion and contraction of the second semiconductor element and the thermal expansion and contraction of the wiring board does not occur. For this reason, even though the diameter of the second via conductor is still small, cracks are not formed between the second via conductors and the second lower-layer conductor.

### BRIEF DESCRIPTION OF THE DRAWINGS

FIG. 1A is a schematic upper view showing an embodiment of a wiring board according to a first aspect of the present invention, and FIG. 1B is a side sectional view along an X-X line in FIG. 1A.

FIG. 2 is a schematic upper view showing another embodiment of the wiring board according to the first aspect of the present invention.

FIG. 3 is a schematic upper view showing yet another embodiment of the wiring board according to the first aspect of the present invention.

FIG. 4A is a schematic upper view showing still another embodiment of the wiring board according to the first aspect of the present invention, and FIG. 4B is a side sectional view along a Z-Z line in FIG. 4A.

FIG. 5A is a schematic upper view showing an embodiment of a wiring board according to a second aspect of the present invention, and FIG. 5B is a side sectional view along an X-X line in FIG. 5A.

FIG. 6 is a schematic upper view showing another embodiment of the wiring board according to the second aspect of the present invention.

FIG. 7 is a schematic upper view showing yet another embodiment of the wiring board according to the second aspect of the present invention.

FIG. 8A is a schematic upper view showing still another embodiment of the wiring board according to the second aspect of the present invention, and FIG. 8B is a side sectional view along a Z-Z line in FIG. 8A.

FIG. 9 is a schematic sectional view showing an embodiment of a wiring board according to a third aspect of the present invention.

FIG. 10 is a schematic sectional view showing another embodiment of the wiring board according to the third aspect of the present invention.

FIG. 11 is a schematic sectional view showing still another embodiment of the wiring board according to the third aspect of the present invention.

FIG. 12 is a schematic sectional view showing an embodiment of a wiring board according a fourth aspect of the present invention.

FIG. 13 is a schematic sectional view showing another embodiment of the wiring board according to the fourth aspect of the present invention.

FIG. 14 is a schematic sectional view showing still another embodiment of the wiring board according to the fourth aspect of the present invention.

FIG. 15A is a schematic upper view showing a conventional wiring board, and FIG. 15B is a side sectional view along a Y-Y line in FIG. 15A.

FIG. 16 is a schematic sectional view showing another conventional wiring board.

FIG. 17 is a schematic sectional view showing still another conventional wiring board.

### DESCRIPTION OF EXEMPLARY EMBODIMENTS

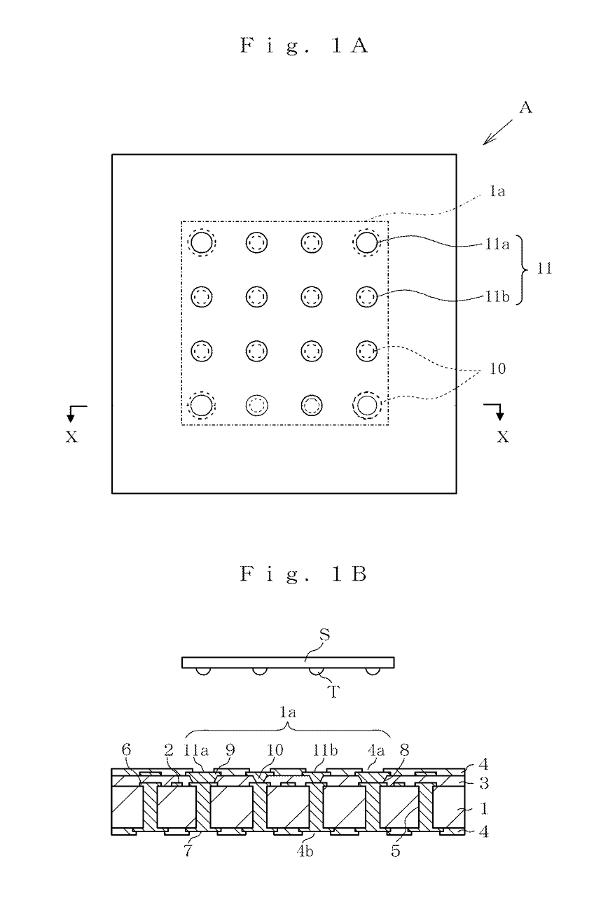

An embodiment of a wiring board according to a first aspect of the present invention will be described below with reference to FIG. 1. FIG. 1A is a schematic upper view of a wiring board A, and FIG. 1B is a side sectional view along an X-X line in FIG. 1A. The wiring board A, as shown in FIG. 1B, includes an insulating board 1, wiring conductors 2, an insulating layer 3, and a solder resist layer 4. On a central portion on the upper surface of the wiring board A, a semiconductor element mounting portion 1a having a shape of a quadrangle for mounting a large size semiconductor element S used for computation or the like is formed.

The insulating board 1 is made of, for example, a glass-epoxy resin. In the insulating board 1, a plurality of through holes 5 that penetrate the insulating board 1 from the upper surface of the insulating board 1 to the lower surface thereof. Some of the wiring conductors 2 are adhered to the upper and lower surfaces of the insulating board 1 and the insides of the through holes 5. The wiring conductors 2 on the upper surface side of the insulating board 1 form lower-layer conductors 6 on the upper surface side of a wiring board A. The wiring conductors 2 on the lower surface side of the insulating board 1 form external connection pads 7 connected to an external electric circuit board. The lower-layer conductors 6 and external connection pads 7 are electrically connected to each other by the wiring conductors 2 adhering to the inside of the through holes 5. The insulating board 1 is formed, for example, as described below. An electric insulating material obtained by impregnating a thermosetting resin such as an epoxy resin or a bismaleimide triazine resin in grass cloth is thermally set under pressure to form an insulating plate. The through holes 5 are formed by drilling, blasting, or laser processing to form the insulating board 1.

The insulating layer 3 is laminated on the upper surface of the insulating board 1. The lower-layer conductors 6 are formed on the lower surface of the insulating layer 3. In the insulating layer 3, a plurality of via holes 8 are formed immediately under first semiconductor element connection pads 11a and second semiconductor element connection pads 11b (will be described later). The insulating layer 3 is formed such that an electric insulating sheet made of a thermosetting resin such as an epoxy resin or a bismaleimide triazine resin is laminated on the insulating board 1 and thermally set in a vacuum state. The via holes 8 are formed by laser processing. After the laser processing, desmear treatment is preferably performed. The via holes 8 are formed by using the lower-layer conductors 6 as lower surfaces.

Some of the wiring conductors 2 are adhered to the upper surface of the insulating layer 3 and the insides of the via holes 8. The wiring conductors 2 adhering to the upper surface of the insulating layer 3 form upper-layer conductors 9 on the upper surface side of the wiring board A. The wiring conductors 2 adhering to the insides of the via holes 8 form via conductors 10 formed integrally with the upper-layer conductors 9. The via conductors 10 are formed in the via holes 8, respectively, to connect the upper-layer conductors 9 and the lower-layer conductors 6 to each other. The wiring conductors 2 (lower-layer conductors 6 and upper-layer conductors 9) and the via conductors 10 are made of a good conductor such as copper plating and formed by, for example, a known semi-adaptive method.

On the semiconductor element mounting portion 1a, some of the upper-layer conductors 9 form the semiconductor element connection pads 11 connected to the electrodes T of the semiconductor element S. The semiconductor element connection pads 11 are formed into a lattice pattern on the semiconductor element mounting portion 1a. The semiconductor element connection pads 11 are connected to the lower-layer conductors 6 by the via conductors 10 formed immediately under the semiconductor element connection pads 11. The semiconductor element connection pads 11 include first semiconductor element connection pads 11a located at outer peripheral corner portions of the semiconductor element mounting portion 1a and the second semiconductor element connection pads 11b located at a portion other than the outer peripheral corner portion.

The solder resist layer 4 is adhered to the upper surface of the insulating layer 3 and the lower surface of the insulating board 1. The solder resist layer 4 on the upper surface of the insulating layer 3 has first openings 4a for exposing the semiconductor element connection pads 11. The solder resist layer 4 on the lower surface of the insulating board 1 has the second openings 4b for exposing the external connection pads 7. The solder resist layer 4, for example, is formed such that a resin paste or film made of an electric insulating material containing a thermosetting resin such as an epoxy resin or a polyimide resin is applied and adhered to the upper surface of the insulating board 1 to be thermally set.

The electrodes T of the semiconductor element S are connected to the corresponding first and second semiconductor element connection pads 11a and 11b through solder, respectively, and the external connection pads 7 are connected to wiring conductors of an external electric circuit board through solder, so that the semiconductor element S operates by being electrically connected to the external electric circuit board.

The diameter of each of the via holes 8 formed under the first semiconductor element connection pads 11a is preferably about 28 to 33 μm. On the other hand, the diameter of each of the via holes 8 formed under the second semiconductor element connection pads 11b is preferably about 20 to 25 μm. For this reason, the diameter of the via conductors 10 formed in each of the via holes 8 formed immediately under the first semiconductor element connection pads 11a is larger than the diameter of the via conductors 10 formed in each of the via holes 8 formed immediately under the second semiconductor element connection pads 11b. The diameter of each of the via conductors 10 connected to the first semiconductor element connection pads 11a is preferably made larger than the diameter of each of the via conductors 10 connected to the second semiconductor element connection pads 11b by about 5 to 10 μm.

Thus, when a connection surface between the via conductors 10 to which the first semiconductor element connection pads are connected and the lower-layer conductors 6 is increased, a bonding strength between the via conductors 10 connected to the first semiconductor element connection pads 11a and the lower-layer conductors 6 can be improved. Thus, at the outer peripheral corner portions of the semiconductor element mounting portion 1a located at a position being distant from a central portion of the semiconductor element mounting portion 1a, cracks can be suppressed from being formed in a bonding surface between the via conductors 10 and the lower-layer conductors 6 at the outer peripheral corner portions of the semiconductor element mounting portion 1a by stress generated by a difference between the thermal expansion and contraction of the semiconductor element S and the thermal expansion and contraction of the wiring board A. As a result, the wiring board A that can stably operate the semiconductor element S can be provided.

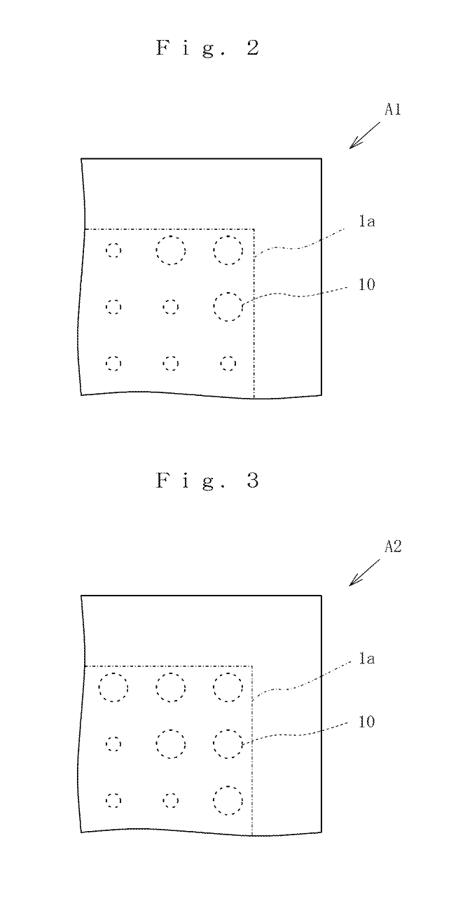

On the wiring board A shown in FIG. 1, the diameter of only one of the via conductors 10 formed at the outer peripheral corner portions of the semiconductor element mounting portion 1a is larger than those of the other via conductors 10. However, as in a wiring board A1 shown in FIG. 2 and a wiring board A2 shown in FIG. 3, the diameters of the plurality of via conductors 10 formed at the outer peripheral corner portions of the semiconductor element mounting portion 1a may be made larger than the diameters of the other via conductors 10.

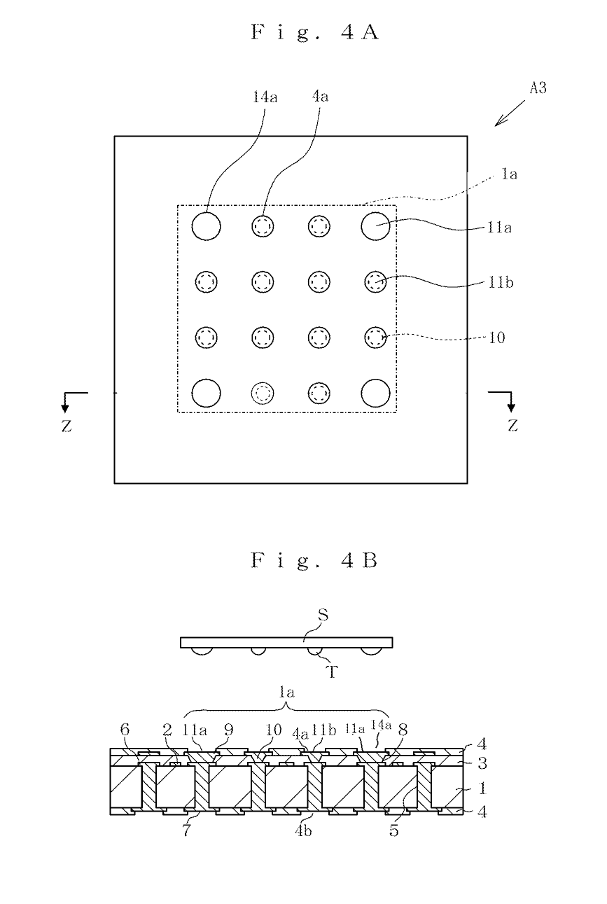

Furthermore, in the wiring board A shown in FIG. 1, on the semiconductor element mounting portion 1a, the opening diameters of openings 4a that expose the first semiconductor element connection pads 11a and the second semiconductor element connection pads 11b are equal to each other. However, as in a wiring board A3 shown in FIG. 4, the opening diameters of openings 14a that expose the first semiconductor element connection pads 11a may be made larger than the opening diameters of the openings 4a that expose the second semiconductor element connection pads 11b. As a result, at each outer peripheral corner portion of the semiconductor element mounting portion 1a on which stress generated by a difference between the thermal expansion and contraction of the semiconductor element S and the thermal expansion and contraction of the wiring board A3 is concentrated, a connection area between the electrodes T of the semiconductor element S and the first semiconductor element connection pads 11a is increased to make it possible to improve the bonding strength therebetween. Thus, even at each of the outer peripheral corner portions of the semiconductor element mounting portion 1a, the connection between the semiconductor element S and the wiring board A3 can be tightly maintained.

As shown in FIG. 2 and FIG. 3, when the plurality of via conductors 10 are formed at the outer peripheral corner portions of the semiconductor element mounting portion 1a to have diameters larger than those of the other via conductors 10, the opening diameters of the plurality of openings that expose the semiconductor element connection pads formed integrally with the via conductors 10 having the large diameters may be increased.

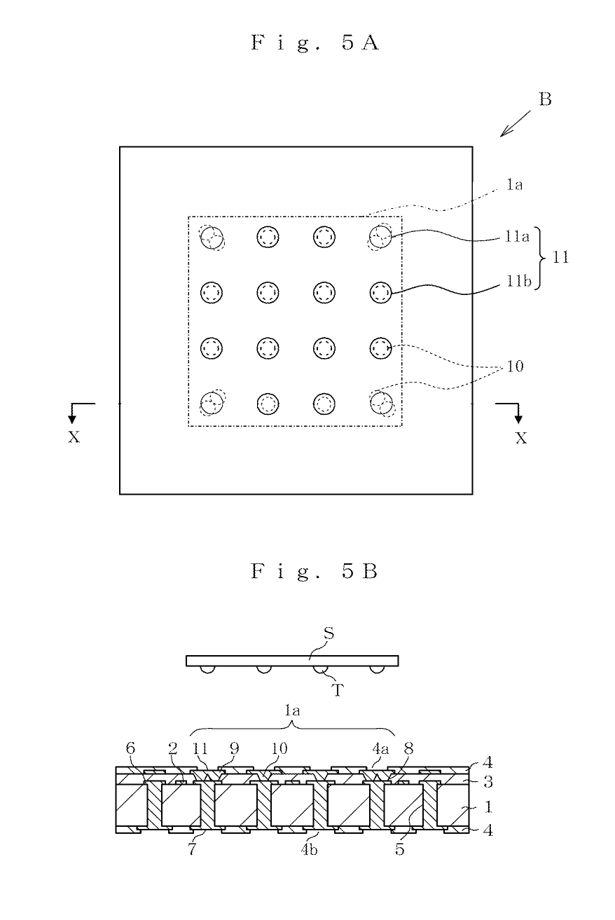

An embodiment of a wiring board according to a second aspect of the present invention will be described below with reference to FIG. 5. FIG. 5A is a schematic upper view of a wiring board B, and FIG. 5B is a side sectional view along an X-X line in FIG. 5A. In the wiring board B shown in FIG. 5, the same reference characters as those of the wiring board A shown in FIG. 1 denote the same parts as in the wiring board A, and a description thereof will be omitted.

In the wiring board B shown in FIG. 5, the two via conductors 10 are formed for each of the first semiconductor element connection pads 11a. More specifically, in the insulating layer 3, the two via holes 8 are formed immediately under each of the first semiconductor element connection pads 11a, and the via conductors 10 are formed in the via holes 8, respectively. The via holes 8 immediately under the first semiconductor element connection pads 11a may have the same diameters of the via holes 8 formed at the other portions.

The planar shapes of the upper-layer conductors 9 to serve as the first semiconductor element connection pad 11a may be not only circular shapes, but also elliptical shapes or quadrangles (rectangles, squares, or the like). When the shape is an elliptical shape or a quadrangle, the two via conductors 10 can be formed on the lower sides of the upper-layer conductors 9 while the areas of the upper-layer conductors 9 is suppressed from being increased.

In the wiring board B shown in FIG. 5, the two via conductors 10 are formed for each of the first semiconductor element connection pads 11a. Thus, since the two via conductors 10 are connected to the lower-layer conductors 6 with respect to each of the first semiconductor element connection pads 11a, a connection surface between the via conductors 10 and the lower-layer conductors 6 increases to make it possible to improve a bonding strength between the via conductors 10 and the lower-layer conductors 6. Thus, at the outer peripheral corner portions of the semiconductor element mounting portion 1a located at a position being distant from a central portion of the semiconductor element mounting portion 1a, cracks can be suppressed from being formed in a bonding surface between the via conductors 10 and the lower-layer conductors 6 at the outer peripheral corner portions of the semiconductor element mounting portion 1a by stress generated by a difference between the thermal expansion and contraction of the semiconductor element S and the thermal expansion and contraction of the wiring board B. As a result, the wiring board B that can stably operate the semiconductor element S can be provided.

The stress generated by the difference between the thermal expansion and contraction of the semiconductor element S and the thermal expansion and contraction of the wiring board B is generated along a direction connecting each of the via conductors 10 and the center of the semiconductor element mounting portion 1a. For this reason, the two via conductors 10 formed for each of the first semiconductor element connection pads 11a are arranged to be aligned along a direction toward the center of the semiconductor element mounting portion 1a.

In the wiring board B shown in FIG. 5, although the two via conductors 10 are formed for each of the first semiconductor element connection pads 11a, three or more via conductors 10 may be formed, and the number of via conductors 10 may be changed depending on the different first semiconductor element connection pads 11a. Furthermore, a plurality of via conductors may be formed for each of the second semiconductor element connection pads 11b. In this case, the number of via conductors 10 formed for each of the first semiconductor element connection pads 11a is preferably larger than the number of via conductors 10 formed for each of the second semiconductor element connection pads 11b.

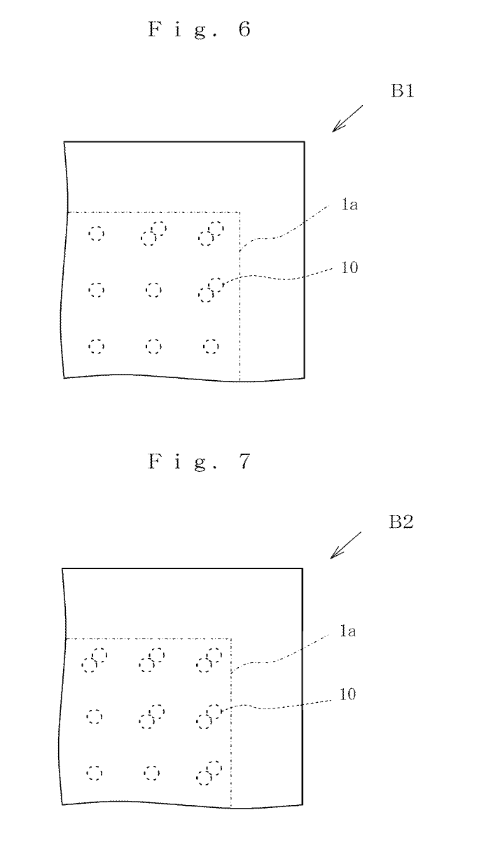

In the wiring board B shown in FIG. 5, the first semiconductor element connection pad 11a on which the two via conductors 10 are formed is only one semiconductor element connection pad 11 formed at each of the outer peripheral corner portions of the semiconductor element mounting portion 1a. However, as in a wiring board B1 shown in FIG. 6 and a wiring board B2 shown in FIG. 7, the two or three or more via conductors 10 may be formed for each of the plurality of first semiconductor element connection pads 11a formed at the outer peripheral corner portions of the semiconductor element mounting portion 1a.

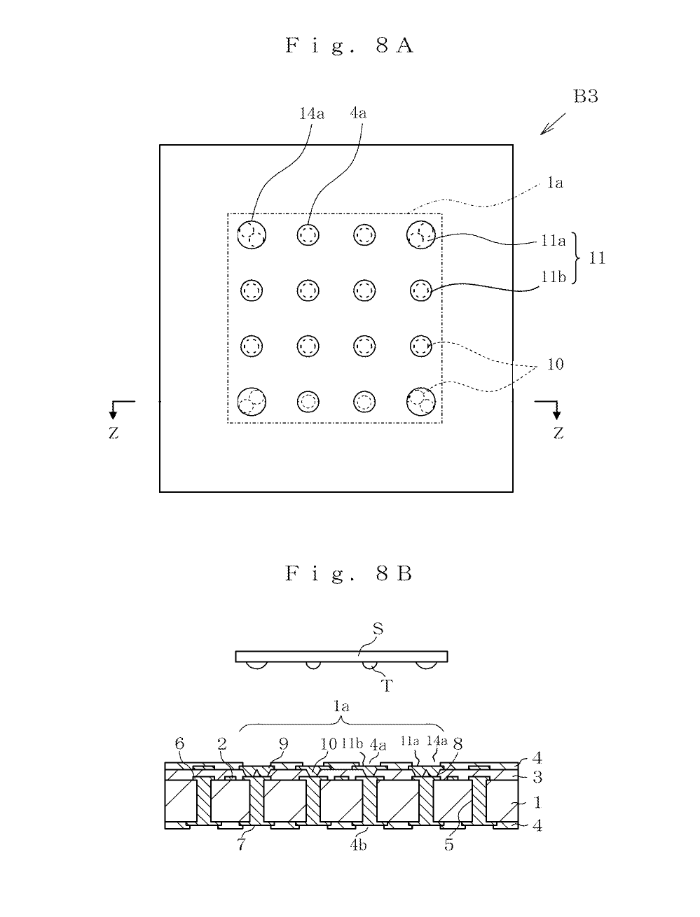

Furthermore, in the wiring board B shown in FIG. 5, on the semiconductor element mounting portion 1a, the opening diameters of openings 4a that expose the first semiconductor element connection pads 11a and the second semiconductor element connection pads 11b are equal to each other. However, as in a wiring board B3 shown in FIG. 8, the opening diameters of openings 14a that expose the first semiconductor element connection pad 11a on which the two via conductors 10 are formed may be made larger than the opening diameters of the openings 4a that expose the second semiconductor element connection pad 11b on which only one via conductor 10 is formed. As a result, at each outer peripheral corner portion of the semiconductor element mounting portion 1a on which stress generated by a difference between the thermal expansion and contraction of the semiconductor element S and the thermal expansion and contraction of the wiring board B3 is concentrated, a connection area between the electrodes T of the semiconductor element S and the semiconductor element connection pads 11 is increased to make it possible to improve the bonding strength therebetween. Thus, the connection between the semiconductor element S and the wiring board B3 can be tightly maintained.

As shown in FIG. 6 and FIG. 7, when the plurality of first semiconductor element connection pads 11a are formed at the outer peripheral corner portions of the semiconductor element mounting portion 1a, the opening diameters of the plurality of openings that expose the semiconductor element connection pads 11a formed integrally with the two via conductors 10 may be increased.

An embodiment of a wiring board according to a third aspect of the present invention will be described below with reference to FIG. 9. A wiring board C shown in FIG. 9, includes the insulating board 1, the wiring conductors 2, the insulating layer 3, and the solder resist layer 4. On a central portion on the upper surface of the wiring board C, a first mounting portion 1a for mounting a large size semiconductor element S1 used for computation or the like is formed. On a peripheral portion of the upper surface of the wiring board C, second mounting portions 1b for mounting small size second semiconductor elements S2 such as an element for memory is formed. Materials of the insulating board, the wiring conductor, the insulating layer, and the solder resist layer, processing methods thereof, and the like are the same as described above, and a description thereof will be omitted.

A plurality of first via holes 8a are formed in the insulating layer 3 on the first mounting portion 1a. A plurality of second via holes 8b are formed in the insulating layer 3 on the second mounting portions 1b. The first via holes 8a and the second via holes 8b are formed to use the lower-layer conductors 6 as bottom surfaces. Some of the wiring conductors 2 are adhered to the upper surface of the insulating layer 3 and the insides of the first and second via holes 8a and 8b. The wiring conductors 2 adhering to the upper surface of the insulating layer 3 form upper-layer conductors 9 on the upper surface side of the wiring board A. The wiring conductors 2 adhering to the insides of the first and second via holes 8a and 8b form first via conductors 10a and second via conductors 10b formed integrally with the upper-layer conductors 9. The first via conductors 10a and the second via conductors 10b are formed in the first via holes 8a and the second via holes 8b, respectively, to connect the upper-layer conductors 9 and the lower-layer conductors 6 to each other. Materials of the via holes, the wiring conductors (lower-layer conductors and upper-layer conductors), and the via conductors and processing methods thereof are the same as described above, and a description thereof will be omitted.

On the first mounting portion 1a, some of the upper-layer conductors 9 form the first semiconductor element connection pads 11a connected to the electrodes T1 of the first semiconductor element S1. The first semiconductor element connection pads 11a are formed with an arrangement corresponding to that of the electrodes T1 of the first semiconductor element S1. The first semiconductor element connection pads 11a are connected to the lower-layer conductors 6 with the first via conductors 10a formed immediately under the first semiconductor element connection pads 11a. On the other hand, on the second mounting portions 1b, others of the upper-layer conductors 9 form the second semiconductor element connection pads 11b connected to the electrodes T2 of the second semiconductor elements S2. The second semiconductor element connection pads 11b are formed to have an arrangement corresponding to that of the electrodes T2 of the second semiconductor elements S2. The second semiconductor element connection pads 11b are connected to the lower-layer conductors 6 with the second via conductors 10b formed immediately under the second semiconductor element connection pads 11b.

The electrodes T1 of the first semiconductor element S1 are arranged with the first electrode pitch P1 that is relatively large, and the second semiconductor elements S2 are arranged at the second electrode pitch P2 smaller than the first electrode pitch P1. The first electrode pitch P1 is about 150 to 160 μm, and the second electrode pitch P2 is about 50 to 60 p.m.

The solder resist layer 4 is adhered to the upper surface of the insulating layer 3 and the lower surface of the insulating board 1. The solder resist layer 4 on the upper surface side has the first openings 4a and third openings 4c for exposing the first and second semiconductor element connection pads 11a and 11b. The solder resist layer 4 on the lower surface side has second openings 4b for exposing the external connection pads 7.

The opening diameters of the first openings 4a may be equal to the opening diameters of the third openings 4c, or may be larger than the opening diameters of the third openings 4c. However, as in the wiring board C in FIG. 9, the opening diameters of the first openings 4a are preferably larger than the opening diameters of the third openings 4c. In this manner, a connection area between the electrodes T1 of the first semiconductor element S1 and the first semiconductor element connection pads 11a is increased to make it possible to improve bonding strength therebetween. As a result, against stress generated by a difference between the thermal expansion and contraction of the first semiconductor element S1 having diagonal lines longer than the diagonal lines of the second semiconductor element S2 and the thermal expansion and contraction of the wiring board A, the connection between the first semiconductor element S1 and the wiring board C can be tightly maintained.

The electrodes T1 and T2 of the first and second semiconductor elements S1 and S2 are connected to the corresponding first and second semiconductor element connection pads 11a and 11b through solder, respectively, and the external connection pads 7 are connected to wiring conductors of an external electric circuit board through solder, so that the first and second semiconductor elements S1 and S2 operate by being electrically connected to the external electric circuit board.

The diameters of the first via holes 8a are preferably about 28 to 33 μm, and the diameters of the second via holes 8b are preferably 20 to 25 μm. The first and second via conductors 10a and 10b are formed in the first and second via holes 8a and 8b, respectively, and the first via conductors 10a have diameters larger than those of the second via conductors 10b. For this reason, a contact area between the first via conductors 10a and the lower-layer conductors 6 can be increased to make it possible to improve a bonding strength between the first via conductors 10a and the lower-layer conductors 6. Thus, cracks can be suppressed from being formed between the first via conductors 10a and the lower-layer conductors 6 by stress generated by a difference between the thermal expansion and contraction of the first semiconductor element S1 having diagonal lines longer than the diagonal lines of the second semiconductor element S2 and the thermal expansion and contraction of the wiring board C. As a result, the wiring board C that can stably operate the semiconductor element S1 can be provided.

Since the electrode pitch P1 of the first semiconductor element S1 is larger than the electrode pitch P2 of the second semiconductor element S2, even though the diameters of the first via conductors 10a are increased, a sufficient insulating space can be formed between the first via conductors 10a. Furthermore, since the diagonal lines of the second semiconductor element S2 are short, large stress caused by a difference between the thermal expansion and contraction of the second semiconductor element S2 and the thermal expansion and contraction of the wiring board C does not occur. Even though the diameters of the second via conductors 10b are still small, cracks are not formed between the second via conductors 10b and the lower-layer conductors 6.

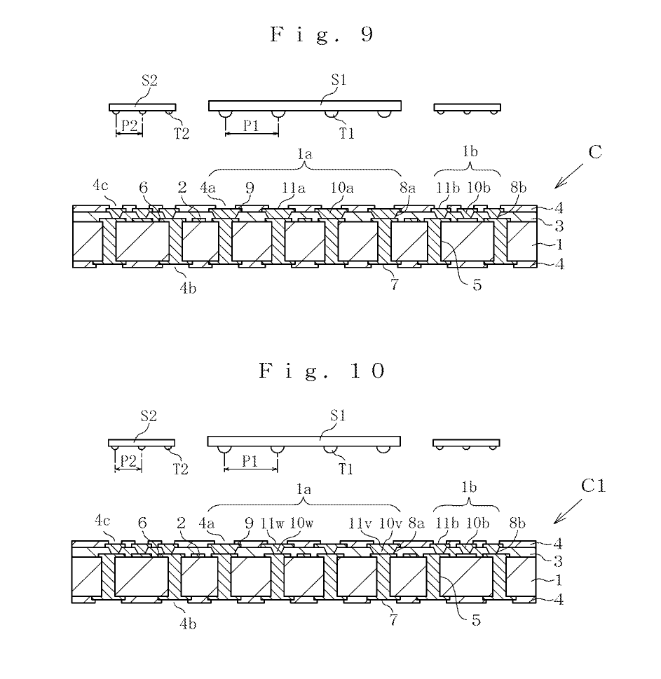

In the wiring board C shown in FIG. 9, the diameters of all the first via conductors 10a are larger than the diameters of the second via conductors 10b. However, as in a wiring board C1 shown in FIG. 10, on the first mounting portion 1a, only the diameters of first via conductors 10v formed integrally with first semiconductor element connection pads 11v arranged on an outer peripheral portion of the first mounting portion 1a may be made larger than the diameters of first via conductors 10w formed integrally with first semiconductor element connection pads 11w arranged on a central portion of the first mounting portion 1a and the diameters of the second via conductors 10b. In this manner, on the outer peripheral portion of the first mounting portion 1a on which stress generated by a difference between the thermal expansion and contraction of the first semiconductor element S1 and the thermal expansion and contraction of the wiring board C1 is especially concentrated, a bonding strength between the first via conductors 10v formed integrally with the first semiconductor element connection pads 11v and the lower-layer conductors 6 can be improved. As a result, cracks can be suppressed from being formed between the first via conductors 10v connected to the first semiconductor element connection pads 11v on the outer peripheral portion of the first mounting portion 1a and the lower-layer conductors 6.

When the first semiconductor element connection pads 11v and 11w arranged on the first mounting portion 1a and the first via conductors 10v and 10w are formed by a semi-additive method and electrolytic plating is adhered in the semi-additive method, a current distribution for electrolytic plating tends to be increased while being concentrated on the outer peripheral portion of the first mounting portion 1a, and decreased while being dispersed on the central portion. For this reason, the precipitation property of the electrolytic plating is improved on the outer peripheral portion of the first mounting portion 1a and is poor on the central portion. On the other hand, as in the wiring board C1 shown in FIG. 10, the diameters of only the first via conductors 10v arranged on the outer peripheral portion of the first mounting portion 1a are increased, and the diameters of the first via conductors 10w arranged on the central portion are kept small. In this case, when electrolytic plating is adhered in the semi-additive method, even on the central portion where the precipitation property of the electrolytic plating is poor, the first via conductors 10w can be preferably precipitated. Thus, the wiring board C1 in which excellent electric connection reliability can be obtained not only on the outer peripheral portion of the first mounting portion 1a, but also on the central portion can be provided.

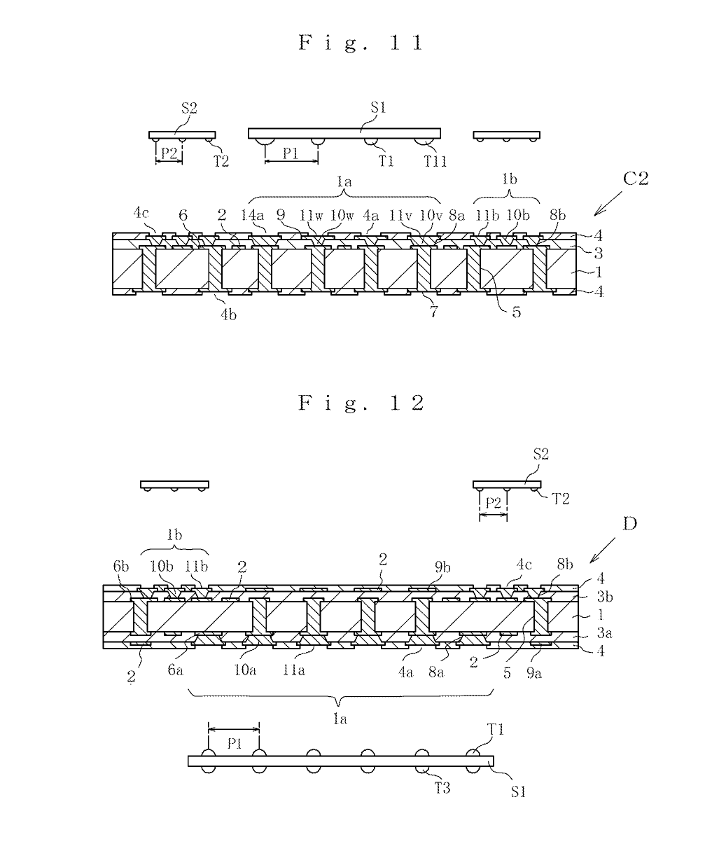

In the wiring board C1 shown in FIG. 10, on the first mounting portion 1a, the diameters that expose the first semiconductor element connection pads 11v arranged on the outer peripheral portion of the first mounting portion 1a and the first semiconductor element connection pads 11w arranged on the central portion of the first mounting portion 1a are equal to each other. However, as in the wiring board C2 shown in FIG. 11, the diameters of the openings 14a that expose the first semiconductor element connection pads 11v may be made larger than the opening diameters of the openings 4a that expose the first semiconductor element connection pads 11w. In this manner, on the outer peripheral portion of the first mounting portion 1a on which stress generated by a difference between the thermal expansion and contraction of the first semiconductor element S1 and the thermal expansion and contraction of the wiring board C2 is especially concentrated, a connection area between the electrodes T11 of the first semiconductor element S1 and the first semiconductor element connection pads 11v can be increased, and a bonding strength therebetween can be improved. As a result, even on the outer peripheral portion of the first mounting portion 1a on which stress generated by a difference between the thermal expansion and contraction of the first semiconductor element S1 and the thermal expansion and contraction of the wiring board C2 is especially concentrated, the connection between the first semiconductor element S1 and the wiring board C2 can be tightly maintained.

An embodiment of a wiring board according to a fourth aspect of the present invention will be described below with reference to FIG. 12. The wiring board D shown in FIG. 12 includes the insulating board 1, the wiring conductors 2, insulating layers 3a and 3b, and the solder resist layer 4. On a central portion on the lower surface of the wiring board D, a first mounting portion 1a for mounting a large size first semiconductor element S1 used for computation or the like is formed. On the outer peripheral portion of the upper surface of the wiring board D, second mounting portions 1b for mounting small size second semiconductor elements S2 such as an element for memory is formed. More specifically, the wiring board D is basically similar to the wiring board C shown in FIG. 9 except that the first mounting portion 1a for mounting the first semiconductor element S1 is formed on the lower surface of the wiring board. Materials of the insulating board, the wiring conductor, the insulating layer, and the solder resist layer, processing methods thereof, and the like are the same as described above, and a description thereof will be omitted.

In the wiring board D shown in FIG. 12, the first mounting portion 1a is formed on the lower surface, and the second mounting portions 1b are formed on the upper surface. For this reason, the wiring conductors 2 and the insulating layers 3a and 3b are arranged on the upper and lower surfaces of the insulating board. The wiring conductors 2 on the lower surface of the insulating board 1 form first lower-layer conductors 6a on the lower surface side of the wiring board D. The wiring conductors 2 on the upper surface of the insulating board 1 form second lower-layer conductors 6b on the upper surface side of the wiring board D. The wiring conductors 2 adhering to the inside of the through holes 5 electrically connect the first lower-layer conductors 6a and the second lower-layer conductors 6b to each other.

The first insulating layer 3a is laminated on the lower surface of the insulating board 1, and the second insulating layer 3b is laminated on the upper surface of the insulating board 1. A plurality of first via holes 8a are formed in the first insulating layer 3a, and a plurality of second via holes 8b are formed in the second insulating layer 3b. The first via holes 8a and the second via holes 8b are formed to have the first lower-layer conductors 6a and the second lower-layer conductors 6b as bottom surfaces, respectively.

Some of the wiring conductors 2 are adhered to the lower surface of the first insulating layer 3a, the insides of the first via holes 8a, the upper surface of the second insulating layer 3b, and the insides of the second via holes 8b. The wiring conductors 2 adhering to the lower surface of the first insulating layer 3a form first upper-layer conductors 9a on the lower surface side of the wiring board D. The wiring conductors 2 adhering to the inside of each of the via hole 8a form the first via conductors 10a formed integrally with the first upper-layer conductors 9a. On the other hand, the wiring conductors 2 adhering to the upper surface of the second insulating layer 3b form second upper-layer conductors 9b on the upper surface side of the wiring board D. The wiring conductors 2 adhering to the inside of each of the second via hole 8b form the second via conductors 10b formed integrally with the second upper-layer conductors 9b. The first via conductors 10a are formed in the first via holes 8a to connect the first upper-layer conductors 9a and the first lower-layer conductors 6a to each other. The second via conductors 10b are formed in each of the second via holes 8b to connect the second upper-layer conductors 9b and the second lower-layer conductors 6b to each other. Materials of the via holes, the wiring conductors (lower-layer conductors and upper-layer conductors), and the via conductors and processing methods thereof are the same as described above, and a description thereof will be omitted.

Some of the first upper layer conductors 9a form the first semiconductor element connection pads 11a connected to the electrodes T1 of the first semiconductor element S1 on the first mounting portion 1a. The first semiconductor element connection pads 11a are formed to have an arrangement corresponding to that of the electrodes T1 of the first semiconductor element S1. The first semiconductor element connection pads 11a are connected to the first lower-layer conductors 6a with the first via conductors 10a formed immediately above (on the insulating board 1 side) the first semiconductor element connection pads 11a. Some of the second upper-layer conductors 9b form the second semiconductor element connection pads 11b connected to the electrodes T2 of the second semiconductor elements S2 on the second mounting portions 1b. The second semiconductor element connection pads 11b are formed to have an arrangement corresponding to that of the electrodes T2 of the second semiconductor elements S2. The second semiconductor element connection pads 11b are connected to the second lower-layer conductors 6b with the second via conductors 10b formed immediately under (on the insulating board 1 side) the second semiconductor element connection pads 11b. Furthermore, in the first semiconductor element S1, the external connection electrodes T3 connected to an external electric circuit board are formed on a surface opposing a surface on which the electrodes T1 are formed.

The electrodes T1 of the first semiconductor element S1 are arranged with a first electrode pitch P1 that is relatively large, and the electrodes T2 of the second semiconductor elements S2 are arranged at a second electrode pitch P2 smaller than the first electrode pitch P1. The first electrode pitch P1 is about 150 to 160 μm, and the second electrode pitch P2 is about 50 to 60 μm.

The solder resist layer 4 is adhered to the lower surface of the first insulating layer 3a and the upper surface of the second insulating layer 3b. The solder resist layer 4 on the first insulating layer 3a side has first openings 4a for exposing the first semiconductor element connection pads 11a. The solder resist layer 4 on the second insulating layer 3b side has the third openings 4c for exposing the second semiconductor element connection pads 11b.

The opening diameters of the first openings 4a may be equal to the opening diameters of the third openings 4c, or may be larger than the opening diameters of the third openings 4c. However, as in the wiring board D in FIG. 12, the opening diameters of the first openings 4a are preferably larger than the opening diameters of the third openings 4c. In this manner, a connection area between the electrodes T1 of the first semiconductor element S1 and the first semiconductor element connection pads 11a is increased to make it possible to improve bonding strength therebetween. As a result, against stress generated by a difference between the thermal expansion and contraction of the first semiconductor element S1 having diagonal lines longer than the diagonal lines of the second semiconductor element S2 and the thermal expansion and contraction of the wiring board D, the connection between the first semiconductor element S1 and the wiring board D can be tightly maintained.

The electrodes T1 and T2 of the first and second semiconductor elements S1 and S2 are connected to the corresponding first and second semiconductor element connection pads 10a and 10b through solder, respectively, and the external connection electrodes T3 are connected to wiring conductors of an external electric circuit board through solder, so that the first and second semiconductor elements S1 and S2 operated by being electrically connected to the external electric circuit board.

The diameters of the first via holes 8a are preferably about 28 to 33 μm, and the diameters of the second via holes 8b are preferably about 20 to 25 μm. Since the first and second via conductors 10a and 10b are formed in the first and second via holes 8a and 8b, respectively, the first via conductors 10a have diameters larger than those of the second via conductors 10b. For this reason, a connection surface between the first via conductors 10a and the first lower-layer conductors 6a is increased to make it possible to improve bonding strength between the first via conductors 10a and the first lower-layer conductors 6a. Thus, cracks can be suppressed from being formed between the first via conductors 10a and the first lower-layer conductors 6a by stress generated by a difference between the thermal expansion and contraction of the first semiconductor element S1 having diagonal lines longer than the diagonal lines of the second semiconductor element S2 and the thermal expansion and contraction of the wiring board D. As a result, the wiring board D that can stably operate the semiconductor element can be provided.

Since the first electrode pitch P1 of the first semiconductor element S1 is larger than the second electrode pitch P2 of the second semiconductor element S2, even though the first via conductors 10a have large diameters, a sufficient insulating space can be made between the first via conductors 10a. Furthermore, since the diagonal lines of the second semiconductor element S2 are short, large stress caused by a difference between the thermal expansion and contraction of the second semiconductor element S2 and the thermal expansion and contraction of the wiring board D is not generated. Thus, even if the diameters of the second via conductors 10b are still small, cracks are not formed between the second via conductors 10b and the second lower-layer conductors 6b.

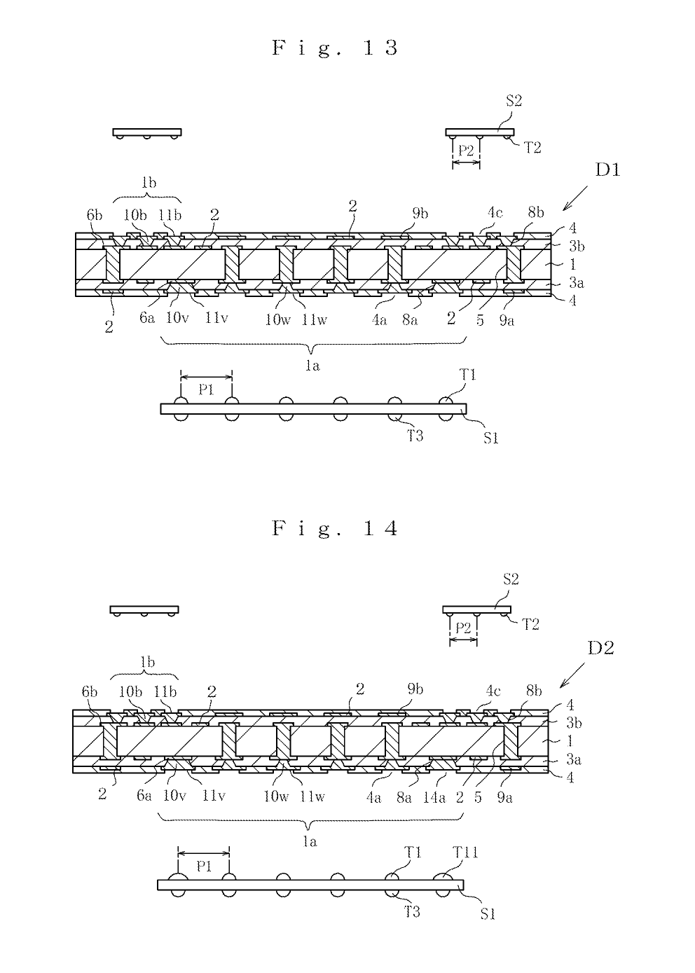

On the wiring board D shown in FIG. 12, the diameters of all the first via conductors 10a are larger than the diameters of the second via conductors 10b. However, as in a wiring board D1 shown in FIG. 13, on the first mounting portion 1a, only the diameters of first via conductors 10v formed integrally with the first semiconductor element connection pads 11v arranged on an outer peripheral portion of the first mounting portion 1a may be made larger than the diameters of first via conductors 10w formed integrally with the first semiconductor element connection pads 11w arranged on a central portion of the first mounting portion 1a and the diameters of the second via conductors 10b. In this manner, on the outer peripheral portion of the first mounting portion 1a on which stress generated by a difference between the thermal expansion and contraction of the first semiconductor element S1 and the thermal expansion and contraction of the wiring board D1 is especially concentrated, bonding strength between the first via conductors 10v formed integrally with the first semiconductor element connection pads 11v and the first lower-layer conductors 6a can be improved. As a result, cracks can be suppressed from being formed between the first via conductors 10v connected to the first semiconductor element connection pads 11v on the outer peripheral portion of the first mounting portion 1a and the first lower-layer conductors 6a.

When the first semiconductor element connection pads 11v arranged on the first mounting portion 1a having large diagonal lines and the first via conductors 10v and the first semiconductor element connection pads 11w and the first via conductors 10w are formed by a semi-additive method and electrolytic plating is adhered in the semi-additive method, a current distribution for electrolytic plating tends to be increased while being concentrated on the outer peripheral portion of the first mounting portion 1a, and decreased while being dispersed on the central portion. For this reason, the precipitation property of the electrolytic plating is improved on the outer peripheral portion of the first mounting portion 1a and is poor on the central portion. On the other hand, as in the wiring board D1 shown in FIG. 13, the diameters of only the first via conductors 10v arranged on the outer peripheral portion of the first mounting portion 1a are increased, and the diameters of the first via conductors 10w arranged on the central portion are kept small. In this case, when electrolytic plating is adhered in the semi-additive method, even on the central portion where the precipitation property of the electrolytic plating is poor, the first via conductors 10w can be preferably precipitated. Thus, the wiring board D1 in which excellent electric connection reliability can be obtained not only on the outer peripheral portion of the first mounting portion 1a, but also on the central portion.

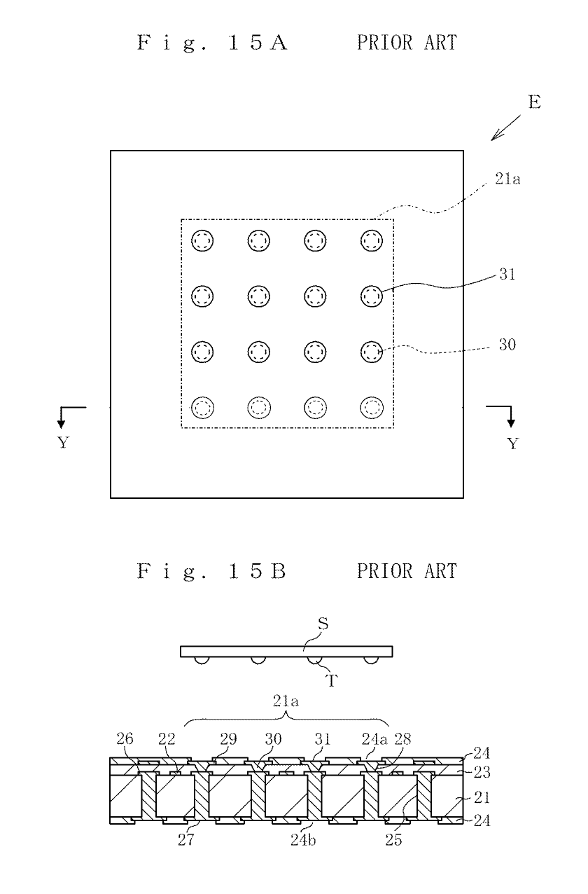

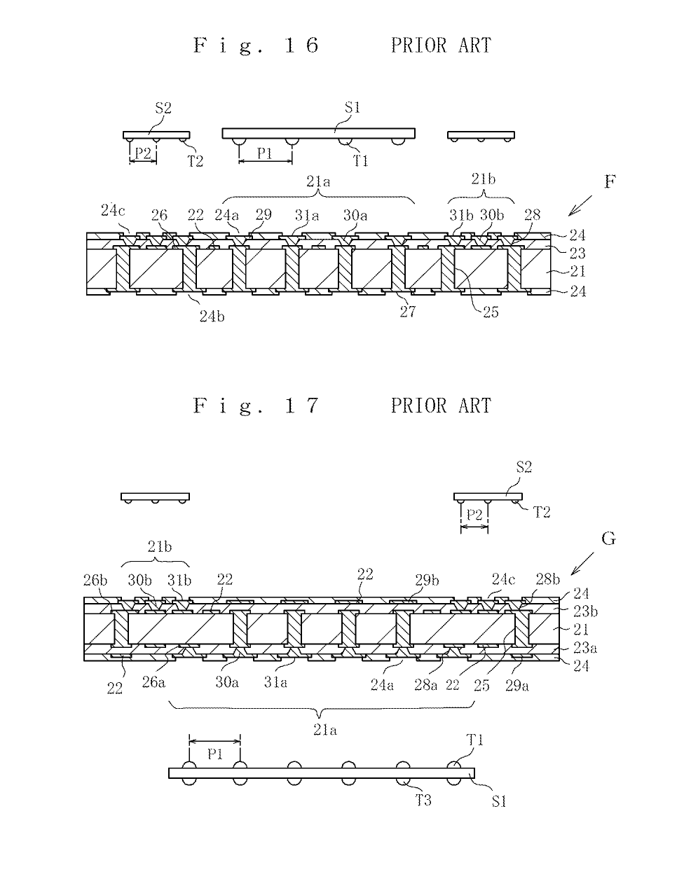

Furthermore, in the wiring board D1 shown in FIG. 13, on the first mounting portion 1a, the opening diameters of the openings 4a that expose the first semiconductor element connection pads 11v arranged at the outer peripheral portion of the first mounting portion 1a and the first semiconductor element connection pads 11w arranged on the central portion of the first mounting portion 1a are equal to each other. However, as in the wiring board D2 shown in FIG. 14, the opening diameters of the openings 14a that expose the first semiconductor element connection pads 11v may be made larger than the opening diameters of the openings 4a that expose the first semiconductor element connection pads 11w. In this manner, on the outer peripheral portion of the first mounting portion 1a on which stress generated by a difference between the thermal expansion and contraction of the first semiconductor element S1 and the thermal expansion and contraction of the wiring board D2 is especially concentrated, a connection area between the electrodes T11 of the first semiconductor element S1 and the first semiconductor element connection pads 11v is increased to make it possible to improve a bonding strength therebetween. As a result, even on the outer peripheral portion of the first mounting portion 1a on which stress generated by a difference between the thermal expansion and contraction of the first semiconductor element S1 and the thermal expansion and contraction of the wiring board D2 is especially concentrated, the connection between the first semiconductor element S1 and the wiring board D2 can be tightly maintained.

The present invention is not limited to the embodiments described above, and various modifications can be made without departing from the spirit and scope of the present invention. On the wiring board A according to the first aspect of the present invention, the wiring board B according to the second aspect, the wiring board C according to the third aspect, only one insulating layer 3 is laminated on the upper surface of the insulating board 1. However, the wiring boards according to the first aspect, the second aspect, and the third aspect of the present invention may have, for example, structures in each of which a plurality of insulating layers made of the same electric insulating material or different electric insulating materials are laminated, or may have structures in each of which one insulating layer or a plurality of insulating layers are laminated on the lower surface side of the insulating board 1.

Furthermore, in the wiring board D according to the fourth aspect of the present invention, only one first insulating layer 3a and only one second insulating layer 3b are formed on the upper and lower surfaces of the insulating board 1, respectively. However, the wiring board according to the fourth aspect of the present invention may have, for example, a structure in which a plurality of insulating layers made of the same electric insulating material or different electric insulating materials are laminated.

What is claimed is:

1. A wiring board comprising:
an insulating layer having lower-layer conductors on a lower surface of the insulating layer;
a semiconductor element mounting portion formed on the insulating layer;
a plurality of semiconductor element connection pads arranged in a lattice pattern on the semiconductor element mounting portion;
via holes formed in the insulating layer under the semiconductor element connection pads with the lower-layer conductors as bottom surfaces; and
via conductors formed integrally with the semiconductor element connection pads and formed in the via holes to be electrically connected to the lower-layer conductor, wherein
the semiconductor element connection pads include first semiconductor element connection pads formed at outer peripheral corner portions of the semiconductor element mounting portion and other second semiconductor element connection pads, and
diameters of the via conductors connected to the first semiconductor element connection pads are larger than diameters of via conductors connected to the second semiconductor element connection pads.

2. The wiring board according to claim 1, further comprising an insulating board formed on a lower surface side of the insulating layer.

3. The wiring board according to claim 1, wherein a solder resist layer having openings that expose the first and second semiconductor element connection pads is adhered to a surface of the insulating layer, and the diameters of the openings that expose the first semiconductor element connection pads are equal to or larger than the diameters of the openings that expose the second semiconductor element connection pads.

4. A wiring board comprising:
an insulating layer having lower-layer conductors on a lower surface of the insulating layer;
a semiconductor element mounting portion formed on the insulating layer;
a plurality of semiconductor element connection pads arranged in a lattice pattern on the semiconductor element mounting portion;
via holes formed in the insulating layer under the semiconductor element connection pads with the lower-layer conductors as bottom surfaces; and
via conductors formed integrally with the semiconductor element connection pads and formed in the via holes to be electrically connected to the lower-layer conductor, wherein
the semiconductor element connection pads include first semiconductor element connection pads formed at outer peripheral corner portions of the semiconductor element mounting portion and other second semiconductor element connection pads, and
with respect to at least the first semiconductor element connection pads, a plurality of via conductors are formed for each of the first semiconductor element connection pads.

5. The wiring board according to claim 4, further comprising an insulating board formed on a lower surface side of the insulating layer.

6. The wiring board according to claim 4, wherein the plurality of via conductors are arranged to be aligned along a direction toward a center of the semiconductor element mounting portion.

7. The wiring board according to claim 4, wherein one via conductor is formed for each of the second semiconductor element connection pads, a solder resist layer having openings that expose the first and second semiconductor element connection pads is adhered to a surface of the insulating layer, and diameters of the openings that expose the first semiconductor element connection pads are equal to or larger than the diameters of the openings that expose the second semiconductor element connection pads.

8. A wiring board comprising:
an insulating layer having lower-layer conductors on a lower surface of the insulating layer;
a first mounting portion formed on the insulating layer and on which a first semiconductor element having a first electrode pitch is mounted;
a second mounting portion formed on the insulating layer and on which a second semiconductor element having a second electrode pitch smaller than the first electrode pitch and having diagonal lines shorter than diagonal lines of the first semiconductor element is mounted;
first semiconductor element connection pads formed on the first mounting portion with the same pitch as the first electrode pitch;
second semiconductor element connection pads formed on the second mounting portion with the same pitch as the second electrode pitch;
first via holes formed in the insulating layer under the first semiconductor element connection pads;
second via holes formed in the insulating layer under the second semiconductor element connection pads;
first via conductors formed integrally with the first semiconductor element connection pads and formed in the first via holes to be electrically connected to the lower-layer conductor, and
second via conductors formed integrally with the second semiconductor element connection pads and formed in the second via holes to be electrically connected to the second lower-layer conductor, wherein
diameters of the first via conductors are larger than the diameters of the second via conductors.

9. The wiring board according to claim 8, further comprising an insulating board formed on a lower surface side of the insulating layer.

10. The wiring board according to claim 8, wherein diameters of the first via conductors formed on an outer peripheral portion of the first mounting portion are larger than diameters of the first via conductors formed on a central portion of the first mounting portion.

11. The wiring board according to claim 8, wherein a solder resist layer having openings that expose the first and second semiconductor element connection pads is adhered to a surface of the insulating layer, and diameters of the openings that expose the first semiconductor element connection pads are equal to or larger than diameters of the openings that expose the second semiconductor element connection pads.

12. The wiring board according to claim 10, wherein a solder resist layer having openings that expose the first and second semiconductor element connection pads is adhered to a surface of the insulating layer, and diameters of the openings that expose the first semiconductor element connection pads on the outer peripheral portion of the first mounting portion are equal to or larger than diameters of the openings that expose the first semiconductor element connection pads on the central portion of the first mounting portion and diameters of the openings that expose the second semiconductor element connection pads.

13. A wiring board comprising:
an insulating board having first lower-layer conductors on a lower surface of the insulating board and second lower-layer conductors on an upper surface of the insulating board;
a first insulating layer laminated on the lower surface of the insulating board to cover the first lower-layer conductor;
a second insulating layer laminated on the upper surface of the insulating board to cover the second lower-layer conductor;
a first mounting portion formed on the first insulating layer and on which a first semiconductor element having a first electrode pitch is mounted;
a second mounting portion formed on the second insulating layer and on which a second semiconductor element having a second electrode pitch smaller than the first electrode pitch and having diagonal lines shorter than diagonal lines of the first semiconductor element is mounted;
first semiconductor element connection pads formed with the same pitch as the first electrode pitch on the first mounting portion;
second semiconductor element connection pads formed with the same pitch as the second electrode pitch on the second mounting portion;
first via holes formed in the first insulating layer under the first semiconductor element connection pads;
second via holes formed in the second insulating layer under the second semiconductor element connection pads;
first via conductors formed integrally with the first semiconductor element connection pads and formed in the first via holes to be electrically connected to the first lower-layer conductor; and
second via conductors formed integrally with the second semiconductor element connection pads and formed in the second via holes to be electrically connected to the second lower-layer conductor, wherein
diameters of the first via conductors are larger than diameters of the second via conductors.

14. The wiring board according to claim 13, wherein diameters of the first via conductors formed on the outer peripheral portion of the first mounting portion are larger than diameters of the first via conductors formed on the central portion of the first mounting portion.

15. The wiring board according to claim 13, wherein a solder resist layer having openings that expose the first and second semiconductor element connection pads is adhered to surfaces of the first and second insulating layers, and diameters of the openings that expose the first semiconductor element connection pads are equal to or larger than diameters of the openings that expose the second semiconductor element connection pads.

16. The wiring board according to claim 14, wherein a solder resist layer having openings that expose the first and second semiconductor element connection pads is adhered to surfaces of the first and second insulating layers, and diameters of the openings that expose the first semiconductor element connection pads on the outer peripheral portion of the first mounting portion are equal to or larger than diameters of the openings that expose the first semiconductor element connection pads on the central portion of the first mounting portion and diameters of the openings that expose the second semiconductor element connection pads.
